(19) United States
(12) Patent Application Publication
(10) Pub. No.: US 2011/0012226 A1
(43) Pub. Date: Jan. 20, 2011

(54) SEMICONDUCTOR DEVICE AND METHOD FOR MANUFACTURING THE SAME

(76) Inventor: Doo-Sung Lee, Taebaek-si (KR)

Correspondence Address: SHERR & VAUGHN, PLLC, 620 HERNDON PARKWAY, SUITE 320, HERNDON, VA, 20170, US

(21) Appl. No.: 12/571,473

(22) Filed: Oct. 1, 2009

(30) Foreign Application Priority Data
Oct. 27, 2008 (KR) 10-2008-0105232

(51) Int. Cl. H01L 29/06; H01L 21/762

(52) U.S. Cl. 257/510; 438/424; 257/E21.546; 257/E29.02

(57) ABSTRACT

The manufacturing method includes etching a semiconductor substrate to form a trench, preparing a liner nitride layer over the semiconductor substrate to cover the inner side of the trench, depositing a protective oxide layer over the liner nitride layer, preparing a gap filling dielectric layer over the semiconductor substrate with the trench having the protective oxide layer deposited therein, and planarizing the gap filling dielectric layer to form a device isolation film. To prevent damage to the pad nitride layer and the inner bottom of the trench, the method further includes deposition of a protective oxide layer such as HTO film throughout a surface of the substrate as well as the inner side of the trench, thereby producing a semiconductor device with excellent quality.

The present application claims priority under 35 U.S.C. 119 to Korean Patent Application No. 10-2008-0105232 (filed on Oct. 27, 2008), which is hereby incorporated by reference in its entirety.

### BACKGROUND

Studies and investigations into increasing the operating current of semiconductor devices have recently been conducted. Among these, a method for controlling a strain in a channel region by applying mechanical stress to a semiconductor device has been proposed. A strain occurring in a channel region influences mobility of carriers, and this phenomenon may be used to increase the operating current. More particularly, when a tensile strain occurs in a channel region of a NMOS transistor, the mobility of electron carriers is improved. Also, when a compressive strain is generated in a channel region of a PMOS transistor, the mobility of hole carriers is improved.

Based on such working properties, the method used for semiconductor device isolation often involves shallow trench isolation (hereinafter, referred to as STI) rather than formation of a device isolation film by selective oxidation (LOCal Oxidation of Silicon: LOCOS). STI introduces a gap filling dielectric layer into a shallow trench formed on a semiconductor substrate in order to form a device isolation film. The STI method has the advantage of eliminating size loss problems such as bird's beak, which may occur with the LOCOS method.

However, STI introduces the drawback of complexity in the process, compared to LOCOS. Moreover, STI has other problems such as stress, recess, trench gap fill, etc. For instance, since a trench gap filling process requires simultaneous deposition and etching during HDP-CVD, STI regions may be partially damaged.

FIGS. 1A to 1E are cross-sectional views illustrating a related process for fabrication of a semiconductor device. Referring to FIGS. 1A to 1D, a pad oxide layer 12 and a pad nitride layer 14 are sequentially laminated over a semiconductor substrate 10. After forming a photoresist pattern 16 over the pad nitride layer 14, both the pad nitride layer 14 and the pad oxide layer 12 are etched to form a mask pattern 17 with an opening exposing a surface of the semiconductor substrate 10 in a device isolation region.

After removing the photoresist pattern 16, the mask pattern 17 is used as a mask for etching the semiconductor substrate 10 in the device isolation region, so as to form a trench 18. Alternatively, instead of the mask pattern 17, the photoresist pattern 16 may be used as a mask in an etching process. That is, the pad nitride layer 14, the pad oxide layer 12 and the semiconductor substrate 10 are continuously etched using the photoresist pattern 15 as a mask, so as to form a trench 18.

On the semiconductor substrate 10 having the trench 18, a gap filling dielectric layer 24 composed of a silicon oxide film is formed by HDP-CVD. Then, planarization of the gap filling dielectric layer 24 through chemical mechanical polishing (CMP) may result in a device isolation film 24a. However, such a device isolation film 24a restricts an active region of the semiconductor substrate 10.

### SUMMARY

Embodiments relate to semiconductor devices and a method for fabrication thereof and, more particularly, to a semiconductor device with a shallow trench isolation (STI) structure protected at a top or bottom thereof during high density plasma chemical vapor deposition (HDP-CVD) and a method for manufacturing the same.

As disclosed above, formation of the gap filling dielectric layer 24 in the trench 18 by high density plasma CVD has problems such as damage to the pad nitride layer 14 and/or damage to an inner bottom of the trench 18.

Embodiments relate to a semiconductor device and a method for manufacturing the same which includes depositing a high temperature oxide (HTO) film throughout a surface of a substrate as well as an inner side of a trench, so as to protect a pad nitride layer and an inner bottom of the trench from damage during HDP-CVD or planarization of a gap filling dielectric layer using the formed HTO film and, at the same time, to improve adhesion between a gap filling oxide layer and a liner nitride layer.

### DRAWINGS

FIGS. 1A to 1D are cross-sectional views illustrating a process for fabrication of a semiconductor device according to a related technique.

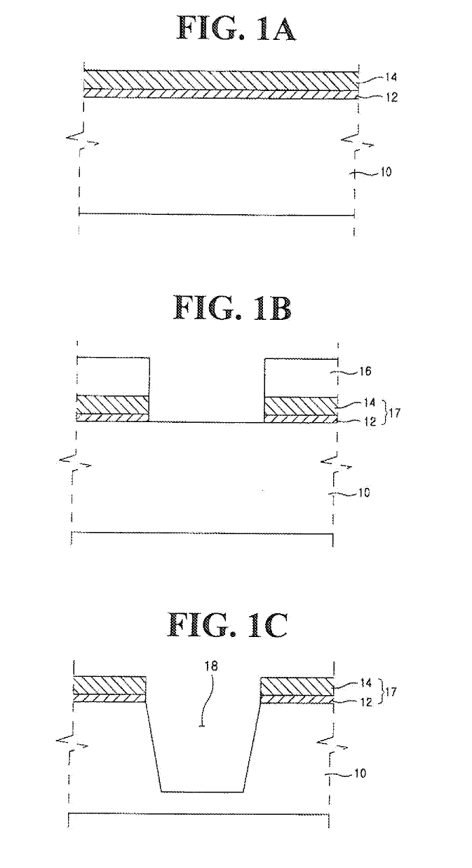

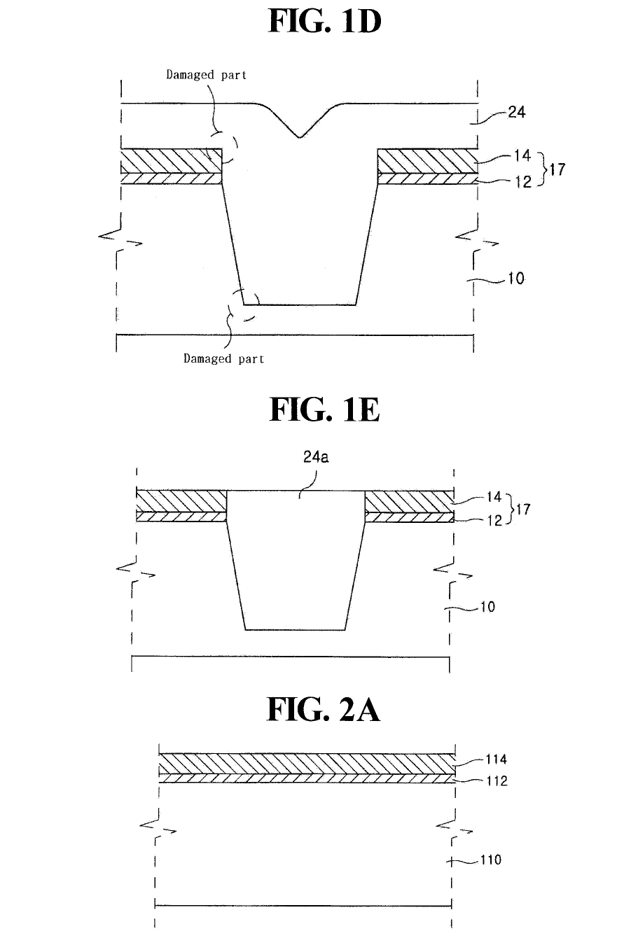

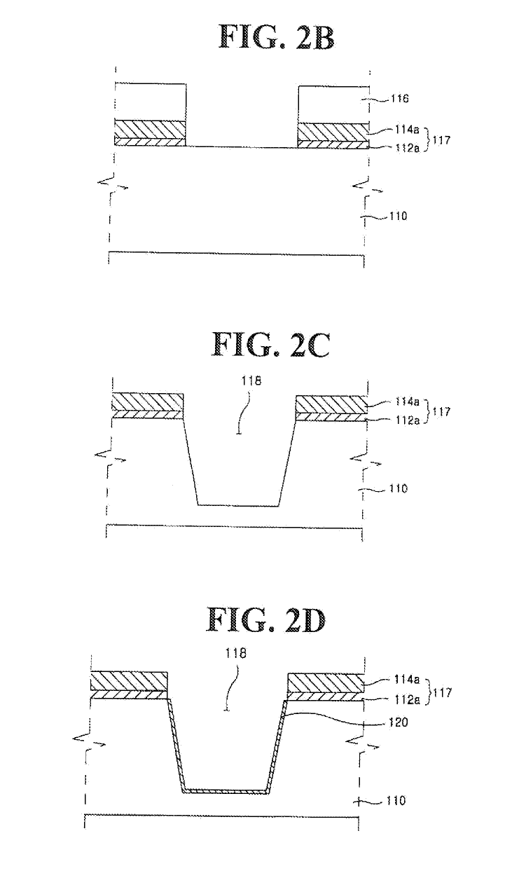

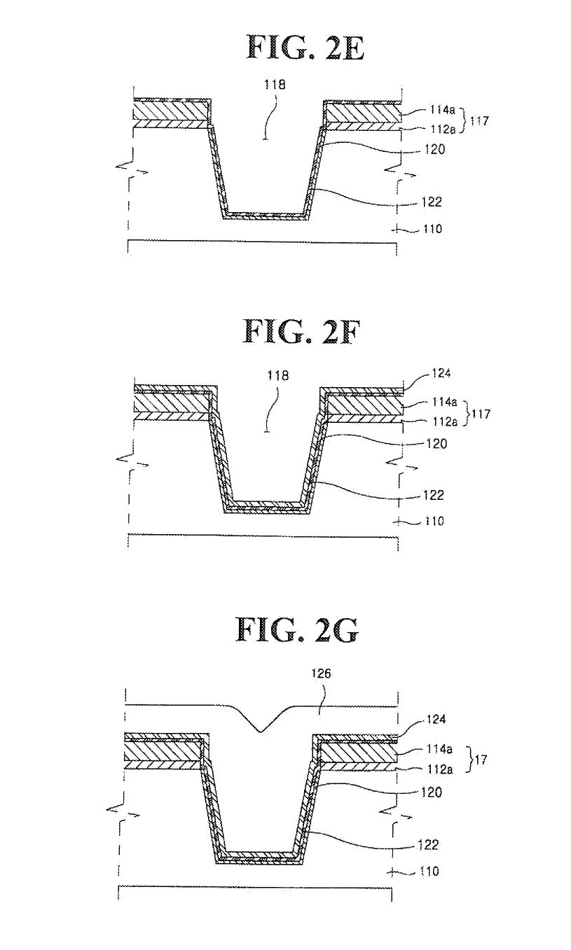

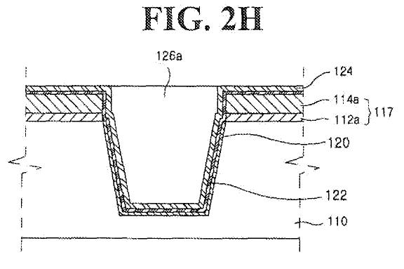

Example FIGS. 2A to 2H are cross-sectional views illustrating a method for manufacturing a semiconductor device according to embodiments.

### DESCRIPTION

A semiconductor device according to embodiments includes: a semiconductor substrate having a trench; a liner nitride layer placed in the trench and over the substrate; a protective oxide layer deposited over the liner nitride layer; and a device isolation film formed by preparing a gap filling dielectric layer over the semiconductor substrate to cover the inner side of the trench having the protective oxide layer deposited thereon, then, planarizing the gap filling dielectric layer.

Before formation of the liner nitride layer, a thin silicon oxide layer may be formed along an inner wall of the trench in order to alleviate stress caused by etching. A thickness of the liner nitride layer may range from 50 Å to 100 Å. A thickness of the HTO film may range from 50 Å to 150 Å.

A method according to embodiments includes: etching a semiconductor substrate to form a trench; preparing a liner nitride layer over the semiconductor substrate to cover the inner side of the trench; depositing a protective oxide layer over the liner nitride layer; and preparing a gap filling dielectric layer over the semiconductor substrate with the trench having the protective oxide layer deposited therein, then, planarizing the gap filling dielectric layer to form a device isolation film.

The foregoing method may further include forming a thin silicon oxide layer along an inner wall of the trench to alleviate stress caused by etching, after formation of the liner nitride layer by etching the semiconductor substrate. A thickness of the formed liner nitride layer may range 50 Å to 100 Å, and a thickness of the protective oxide layer deposited over the liner nitride layer may range from 50 Å to 150 Å.

Embodiments will be described in detail by the following description with reference to the accompanying drawings. Example FIGS. 2A to 2H are cross-sectional views illustrating a method for manufacturing a semiconductor device according to embodiments.

Referring to example FIG. 2A, a pad oxide layer 112 and a pad nitride layer 114 may be sequentially laminated over a semiconductor substrate 110. The pad oxide layer 112 may include a silicon oxide film prepared by thermal oxidation. The pad oxide layer 112 may have a thickness of 40 Å to 65 Å by thermally oxidizing the semiconductor substrate 110 at a temperature of about 800° C. The pad nitride layer 114 may include a silicon nitride film prepared by diffusion or CVD. The pad nitride layer 114 may be formed with a thickness of 800 Å to 1,500 Å at a temperature of about 760° C. The pad nitride layer 114 is not substantially susceptible to oxidation and may be used as a mask to inhibit surface oxidation of the semiconductor substrate 110. The pad oxide layer 112, positioned below the pad nitride layer 114, may alleviate stress occurring at an interface between the semiconductor substrate 110 and the pad nitride layer 114, which in turn prevents potential loss on the surface of the semiconductor substrate 110 caused by the stress.

Referring to example FIG. 2B, a photoresist pattern 116 is formed over the pad nitride layer 114. Using the photoresist pattern 116 as a mask, the pad nitride layer 114 and the pad oxide layer 112 may be etched to obtain a mask pattern 117 for trench (hereinafter, referred to as ‘trench mask pattern’) including a pad nitride pattern 114a and a pad oxide pattern 112a. The pad nitride layer 114 and the pad oxide layer 112 may be etched by a dry-etching process.

Referring to example FIG. 2C, after removing the photoresist pattern 116, the trench mask pattern 117 may be used to etch the semiconductor substrate 110, thus forming a trench 118. The trench 118 may have a thickness of about 3,500 Å to 4,500 Å by etching the semiconductor substrate 110 through anisotropic dry-etching. Instead of using the trench mask pattern 117, the foregoing photoresist pattern 116 may be used as a mask in a continuous etching process that etches the pad nitride layer 114, the pad oxide layer 112 and the semiconductor substrate 112 in sequential order, thereby forming a trench 118. After formation of the trench 118, the mask pattern 117 including the pad nitride pattern 114a and the pad oxide pattern 112a remains over the semiconductor substrate 110 adjacent to the formed trench 118.

Referring to example FIG. 2D, after formation of the trench 118, a thin silicon oxide layer 120 may be formed along the inner wall of the trench 118 in order to alleviate stress caused by the etching process. The thin silicon oxide layer 120 may have a thickness of 40 Å to 80 Å.

Referring to example FIG. 2E, a liner nitride layer 122 may be placed over both the inner wall of the trench 118 having the thin silicon oxide layer 120 formed thereon and the semiconductor substrate 10. More particularly, a liner nitride layer 122 may be provided over the mask pattern 117 adjacent to the trench 118 as well as the inner side of the trench 118 having the thin silicon oxide layer 120 formed thereon. The liner nitride layer 122 may be positioned over the pad nitride pattern used in the etching process in order to form the trench 118.

The liner nitride layer 122 may include a silicon nitride film formed by diffusion or CVD. The liner nitride layer 122 may be formed, for example, with a thickness of 50 Å to 100 Å at a temperature of about 765° C. The liner nitride layer 122 may serve to inhibit oxidation of the inner wall of the trench 118 and to prevent generation of stress during a subsequent process.

As shown in example FIG. 2F, an HTO film 124 may be deposited over the liner nitride layer 122 as a protective oxide layer. The HTO film 124 may prevent damage to the pad nitride layer 114 as well as the inner bottom of the trench 118 during HDP-CVD or planarization of a gap filling dielectric layer 126. Moreover, the HTO film may improve adhesion between the liner nitride layer 122 and the gap filling dielectric layer 126 so as to prevent the gap filling dielectric layer 126 from being partially detached during planarization thereof. The HTO film 124 deposited may have a thickness of 50 Å to 150 Å.

Referring to example FIG. 2G, a gap filling dielectric layer 126 is formed to cover the semiconductor substrate 110 including the trench 118. The gap filling dielectric layer 126 may include a silicon oxide film produced by CVD. The gap filling dielectric layer 126 may be produced, for example, by pyrolysis CVD using monosilane SiH₄ or tetraethyl orthosilicate (TEOS) as a reaction gas. When a width of the trench 118 is not more than 0.20 μm or an aspect ratio is 3 or more, a high gap filling performance process such as pyrolysis CVD using ozone-TEOS (O₃-TEOS) as a reaction gas, HDP-CVD, etc. may be employed.

Referring to example FIG. 2H, planarizing the gap filling dielectric layer 126 may result in a device isolation film 126a. The planarization of the gap filling dielectric layer 126 may be performed by CMP.

Additionally, other related processes including, for example, injection of channel ions, formation of a gate insulating film, a gate electrode, a first spacer, a lightly doped drain (LDD), a second spacer, a source/drain region, silicide and/or a contact plug, and so forth may be conducted to complete manufacturing of the semiconductor device.

Consequently, embodiments may adopt deposition of a liner nitride layer 122 and an HTO film 124 in a trench 118, so as to prevent damage to a pad nitride layer and the inner bottom of the trench during HDP-CVD through the HTO film 124 or planarization of a gap filling dielectric layer.

As disclosed in the above description, the method for manufacturing a semiconductor device according to embodiments may prevent damage to a pad nitride layer and the inner bottom of a trench by deposition of an HTO film throughout a surface of a semiconductor substrate as well as the inner side of the trench, thereby producing a semiconductor with excellent quality.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a semiconductor substrate having a trench formed therein;
a liner nitride layer formed in the trench and over the semiconductor substrate;
a protective oxide layer deposited over the liner nitride layer; and
a device isolation film formed inside the trench and over the protective oxide layer.

2. The apparatus of claim 1, including a pad oxide pattern formed over the semiconductor substrate adjacent to the trench.

3. The apparatus of claim 2, wherein the pad oxide pattern is used as a mask pattern for forming the trench.

4. The apparatus of claim 3, including a pad nitride pattern formed over the pad oxide pattern.

5. The apparatus of claim 4, wherein the liner nitride layer is positioned in the trench and over the pad nitride pattern.

6. The apparatus of claim 1, including a thin silicon oxide layer formed over an inner wall of the trench.

7. The apparatus of claim 6, wherein the liner nitride layer is formed over the thin silicon oxide layer as well as over the semiconductor substrate.

8. The apparatus of claim 1, wherein the protective oxide layer is composed of a high temperature oxide film.

9. The apparatus of claim 1, wherein the liner nitride layer is composed of a silicon nitride film.

10. The apparatus of claim 1, wherein the isolation film is formed by a gap filling dielectric layer.

11. The apparatus of claim 1, wherein the gap filling dielectric layer is planarized.

12. A method comprising:
etching a semiconductor substrate to form a trench;
forming a liner nitride layer over the semiconductor substrate to cover an inner side of the trench;
depositing a protective oxide layer over the liner nitride layer; and
forming a gap filling dielectric layer over the protective oxide layer and the semiconductor substrate including the trench, and then planarizing the gap filling dielectric layer to form a device isolation film.

13. The method of claim 12, wherein the formation of the trench includes: forming a mask pattern for formation of the trench on the semiconductor substrate; and etching the semiconductor substrate using the mask pattern to complete the trench.

14. The method of claim 13, wherein the formation of the mask pattern includes:
forming a pad oxide layer over the semiconductor substrate;
forming a pad nitride layer over the pad oxide layer;
forming a photoresist pattern over the pad nitride layer; and
etching both the pad nitride layer with the photoresist pattern and the pad oxide layer, so as to complete the mask pattern including a pad oxide pattern and a pad nitride pattern.

15. The method of claim 14, wherein the liner nitride layer is positioned over the inner side of the trench as well as the pad nitride pattern.

16. The method of claim 12, wherein a thin silicon oxide layer is formed over an inner wall of the trench before formation of the liner nitride layer.

17. The method of claim 12, wherein the protective oxide layer is composed of a high temperature oxide film.

18. The method of claim 12, wherein the liner nitride layer is composed of a silicon nitride film.

19. The method of claim 12, wherein forming a gap filling dielectric layer includes high density plasma chemical vapor deposition of the dielectric layer.

20. The method of claim 19, wherein the gap filling dielectric layer includes a silicon oxide film.
